(19) United States
(12) Patent Application Publication
(10) Pub. No.: US 2002/0100943 A1
(43) Pub. Date: Aug. 1, 2002

(54) Method of manufacturing semiconductor device, and semiconductor device manufactured thereby

(75) Inventors: Tamotsu Ogata, Tokyo (JP); Yasunori Sogo, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/888,386

(22) Filed: Jun. 26, 2001

(30) Foreign Application Priority Data
Jan. 31, 2001 (JP) 2001-024572

(51) Int. Cl. H01L 21/336; H01L 29/76; H01L 29/94; H01L 31/062; H01L 31/113; H01L 31/119

(52) U.S. Cl. 257/382; 438/300

(57) ABSTRACT

In the process of manufacturing a semiconductor device that has a silicide layer, a buffer film is interposed between the silicide layer and the insulating film to protect the silicide layer from direct influence of the stress imposed by the insulating film. For instance, in a logic circuit region of a semiconductor device, a silicide layer is formed on an impurity region. Then, the silicide layer is covered by a buffer layer, and the buffer layer is covered by an interlayer insulating film. The buffer layer is so formed as to alleviate stress imposed on the silicide layer by the interlayer insulating film.

### BACKGROUND OF THE INVENTION

1. Field of the Invention

The present invention relates to a method of manufacturing a semiconductor device, and more particularly, to a method of forming an insulating film for protecting a silicide layer when the silicide layer is formed on a diffused layer of a logic circuit.

2. BACKGROUND ART

In the processes for manufacturing a system LSI having both a DRAM circuit and a logic circuit, that is, embedded DRAM (hereinafter called “eRAM”),there has been known a method of forming a silicide layer; e.g., CoSi₂, on a diffused layer of a logic circuit (hereinafter called a “silicide process”). The purpose is to speed up the operation of the logic circuit by reducing parasitic resistance or parasitic capacitance arising in the diffused layer of the logic circuit.

FIGS. 5A through,7C are drawings for describing processes for manufacturing a system LSI, including a silicide process. A left-side area in each of the drawings represents a region on a semiconductor substrate in which a DRAM circuit is to be fabricated (hereinafter called a “DRAM circuit region”), and a right-side area in each of the drawings represents a region on the substrate in which a logic circuit is to be fabricated (hereinafter called a “logic circuit region”). Here, the logic circuit may be located around the DRAM circuit.

As shown in FIG. 5A, a gate oxide film 2 and gate electrodes are formed on the semiconductor substrate 1 having an active region and an isolation region formed thereon. The gate electrodes are formed by means of sequentially laying a polysilicon film 3, a tungsten silicide film 4, a TEOS oxide film 5, and a nitride film 6.

The entire surface of the semiconductor substrate 1 is doped with impurities through ion implantation, thereby forming source/drain regions 7, which serve as n⁻type diffused layers, on the DRAM circuit region of the semiconductor substrate 1. Subsequently, as shown in FIG. 5B, an oxide film 8 of about several nanometers in thickness is formed on the sidewall of each of the gate electrodes by means of subjecting the substrate 1 to appropriate oxidation processing. A first insulating film 9 formed from, e.g., a nitride film, is formed on the entire surface of the semiconductor substrate 1 by means of LPCVD.

A resist pattern is formed on the first insulating film 9 in the logic circuit region of the substrate 1. The first insulating film 9 is subjected to dry etching while the resist pattern is used as a mask. As shown in FIG. 5C, a sidewall insulating film 10 is formed from the first insulating film 9 on the side surfaces of the gate electrodes in the logic circuit region. The substrate 1 is doped with impurities through ion implantation; so that n⁺-or p⁺-type diffused layers serving as source/drain regions 11 are formed in the logic circuit region of the semiconductor substrate 1.

A silicide layer is formed in the following manner. First, a silicide protection film formed from, e.g., a TEOS oxide film, is formed on the entire surface of the semiconductor substrate 1. Next, a resist pattern is formed on the silicide protection film, and the substrate 1 is subjected to dry or wet etching while the resist pattern is used as a mask.

The silicide protection film formed in the DRAM circuit region and the silicide protection film formed in the predetermined region of the logic circuit region are removed by means of etching. As shown in FIG. 6A, the silicide protection film 12 remains in only the logic circuit region exclusive of the predetermined region on the diffused layer formed around the predetermined gate electrodes.

Even when the silicide protection film 12 is removed from the DRAM circuit region, the first insulating film 9 formed in the preceding step acts as a silicide protection film. Hence, no silicide layer is formed in the DRAM circuit region on the semiconductor substrate 1.

As shown in FIG. 6B, a silicide layer 13 is formed from, e.g., CoSi₂, in a predetermined region on the diffused layer in the logic circuit region by means of a conventional technique; i.e., a self-align silicide method (salicide method). In the manner as mentioned above, the silicide layer 13 is formed on the diffused layer of the logic circuit.

As shown in FIG. 7A, a second insulating film 14 is formed from, e.g., a nitride film, on the entire surface of the semiconductor substrate 1 by means of an LPCVD method. Subsequently, an interlayer insulating film 15 is formed from a BPSG film by means of an APCVD method. The semiconductor substrate is subjected to high-temperature treatment in a steam (wet) atmosphere in which, for example, hydrogen and oxygen are mixed in the proportions of 1.8 to 1. By means of the heat treatment, the interlayer insulating film 15 becomes fluidized (or reflowed). As a result, the smoothness of the interlayer insulating film 15 in the logic circuit region is improved. Further, the space between the gate electrodes located in the DRAM circuit region is embedded with the interlayer insulating film 15.

Even when the semiconductor substrate 1 is subjected to high-temperature treatment in the steam (wet) atmosphere, the second insulating film 14 still remains on the semiconductor substrate 1 or the silicide layer 13 in the logic circuit region. Hence, the semiconductor substrate 1 or the silicide layer 13 located in the logic circuit region is protected from oxidation. In this way, the second insulating film 14 must possess oxidation resistance against a reflow atmosphere.

Next, a resist pattern is formed on the interlayer insulating film 15 formed in the DRAM region. As shown in FIG. 7B, the interlayer insulating film 15 is subjected to dry etching while the resist pattern is used as a mask. Subsequently, the first insulating film 9 and the second insulating film 14 are subjected to dry etching while the interlayer insulating film 15 is used as a mask.

As a result of dry etching, contact holes are formed in the DRAM circuit region so as to extend from the surface of the interlayer insulating film 15 to the diffused layer by way of opening sections for contact purpose (contact openings).

A resist pattern is formed on the interlayer insulating film 15 formed in the logic circuit region. As shown in FIG. 7C, the interlayer insulating film 15, the second insulating film 14, and the silicide protection film 12 are subjected to dry etching while the resist pattern is used as a mask.

By means of dry etching, there are formed contact holes which extend from the surface of the interlayer insulating film 15 to the diffused layer 11 byway of contact openings, and contact holes which extend from the surface of the interlayer insulating film 15 to the silicide layer 13 by way of contact openings. Simultaneously, there are also formed contact holes, which extend from the surface of the interlayer insulating film 15 to the tungsten silicide film 4 of the gate electrodes by way of contact openings, although not shown.

Subsequently, interconnections and capacitors (not shown) are formed sequentially. A system LSI having the DRAM circuit and the logic circuit mixed thereon has hitherto been manufactured in the manner as mentioned above.

As mentioned above, under the method of manufacturing a semiconductor device including a silicide process, a protective film, such as a nitride film, is formed on the silicide layer for preventing oxidation of the silicide layer during a process of forming a final protective film or an interlayer insulating film.

According to the conventional method, the nitride film is formed directly on the silicide layer, and influence of stress due to the nitride film poses a problem. More specifically, stress due to the nitride film may deteriorate the characteristics of transistors, and may affect yield as well.

The present invention has been conceived to solve the drawbacks set forth and is aimed at improving the reliability of transistors fabricated on the semiconductor substrate.

### SUMMARY OF THE INVENTION

The present invention proposes a new method of manufacturing a semiconductor device that has a silicide layer covered by insulating film.

According to one aspect of the present invention, a method comprises the steps of forming a silicide layer, a buffer film, and an insulating film. A silicide layer is formed on the surface of a semiconductor substrate in an impurity region. A buffer film is formed so that it directly covers the silicide layer. In addition, an insulating film is formed on the buffer film, wherein the buffer film alleviates stress imposed by the insulating film on the silicide layer laid on the semiconductor substrate.

According to another aspect of the present invention, when the semiconductor device is composed of memory and a logic circuit, the method comprising the steps of forming a silicide layer, a buffer film, a resist pattern and an insulating film. A silicide layer is formed on the surface of an impurity region within a logic circuit region. A buffer film is formed so that it directly covers the silicide layer, in a memory region and in the logic circuit region having the silicide layer formed thereon. A resist pattern is formed on top of at least the silicide layer within the logic circuit region, and the buffer film is removed from the memory region by means of etching while the resist pattern is used as a mask. Further, an insulating film is formed so that it covers the logic circuit region and the memory region from which the buffer film has been removed. The buffer film alleviates stress imposed by the insulating film on the silicide layer located within the logic circuit region.

The present invention also proposes a new semiconductor device, which is manufactured by the method mentioned above.

According to another aspect of the present invention, a semiconductor device comprises gate electrodes, a silicide layer, buffer film and an insulating film. Gate electrodes are formed on a gate insulating film laid on a semiconductor substrate. A silicide layer is formed on the surface of an impurity region adjacent to the gate electrodes, on the surface of the semiconductor substrate. A buffer film is formed so that it directly covers the silicide layer. Further, an insulating film is formed on the buffer film, wherein the buffer film alleviates the stress imposed by the insulating film on the silicide layer.

Other and further objects, features and advantages of the invention will appear more fully from the following description.

### BRIEF DESCRIPTION OF THE DRAWINGS

FIGS. 1A through 3C are drawings for describing processes for manufacturing a system LSI according to a preferable embodiment of the present invention.

FIG.4 is a graph showing a hot-carrier characteristic of a transistor according to a preferable embodiment of the present invention.

FIGS. SA through 7C are drawings for describing processes for manufacturing a system LSI in a conventional art.

### DETAILED DESCRIPTION OF THE PREFERRED EMBODIMENT

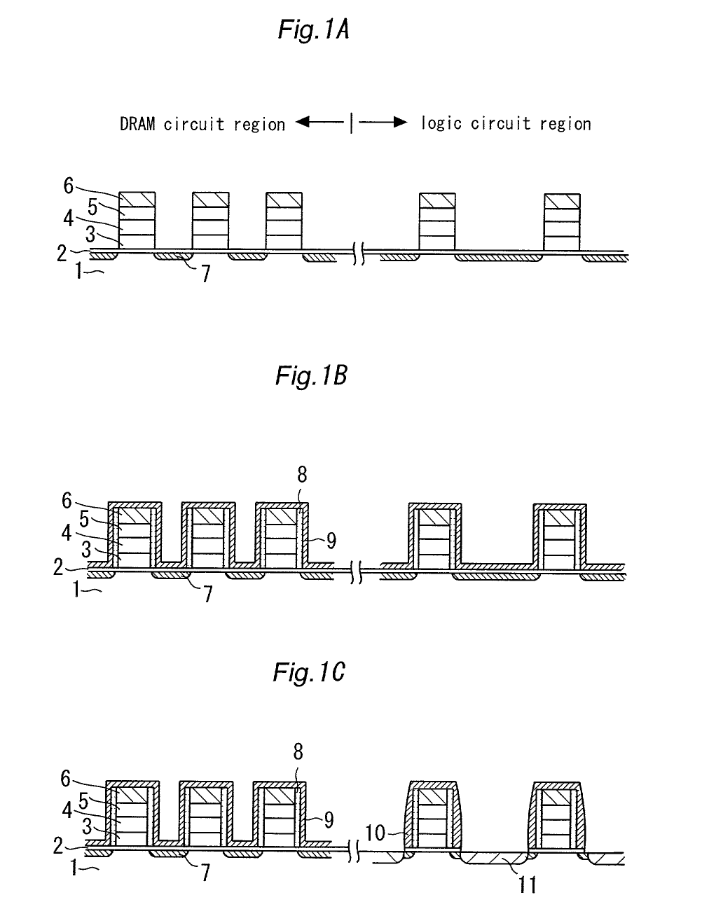

A preferred embodiment of the present invention will be described herein below by reference to FIGS. 1A through 3C. In each of the drawings, a left-side illustration represents a DRAM circuit region, and a right-side illustration represents a logic circuit region. Here, the logic circuit region may be located around the DRAM circuit.

As shown in FIG. 1A, a gate oxide film 2 and gate electrodes are formed on a semiconductor substrate 1 having formed thereon an active region and an isolation region. The gate electrodes are formed by means of sequentially laying a polysilicon film 3, a tungsten silicide film 4, a TEOS oxide film 5, and a nitride film 6.

N⁻-type diffused layers serving as source/drain regions 7 (i.e., impurity regions) are formed in the DRAM circuit region on the semiconductor substrate 1, by means of doping the entire surface of the semiconductor substrate 1 with impurities through ion implantation. Subsequently, as shown in FIG. 1B, an oxide film 8 is formed on the sidewalls of the gate electrodes to a thickness of several nanometers by means of appropriate oxidation processing. A first insulating film 9 is formed from, e.g., a nitride film, on the entire surface of the semiconductor substrate 1 by means of LPCVD. Here, a silicon oxide film may be formed on the sidewalls of the gate electrodes to thickness of a few nanometers or thereabouts by means of CVD, rather than the semiconductor substrate 1 being subjected to oxidation processing.

A resist pattern is formed on the first insulating film 9 formed in the logic circuit region. The first insulating film 9 is subjected to dry etching while the resist pattern is used as a mask. As a result, as shown in FIG. 1C, between the gate electrodes in the logic circuit region, the first insulating film 9 and the gate insulating film 2 on the substrate 1 are removed, and a sidewall insulating film 10 (sidewall) is formed from a first insulating film 9 on the side surfaces of the gate electrodes. Subsequently, n⁺-or p⁺-type diffused layers serving as source/drain regions 11 are formed in the logic circuit region on the semiconductor substrate 1 by means of doping the semiconductor substrate 1 with impurities through ion implantation.

A silicide layer is formed in a predetermined portion of the logic circuit region on the semiconductor substrate 1 by means of the salicide method, in the following manner. First, a silicide protection film formed from, e.g., a TEOS oxide film, is formed on the entire surface of the semiconductor substrate 1 by means of an LPCVD method. Next, a resist pattern is formed on the silicide protection film, and the substrate 1 is subjected to dry or wet etching while the resist pattern is used as a mask.

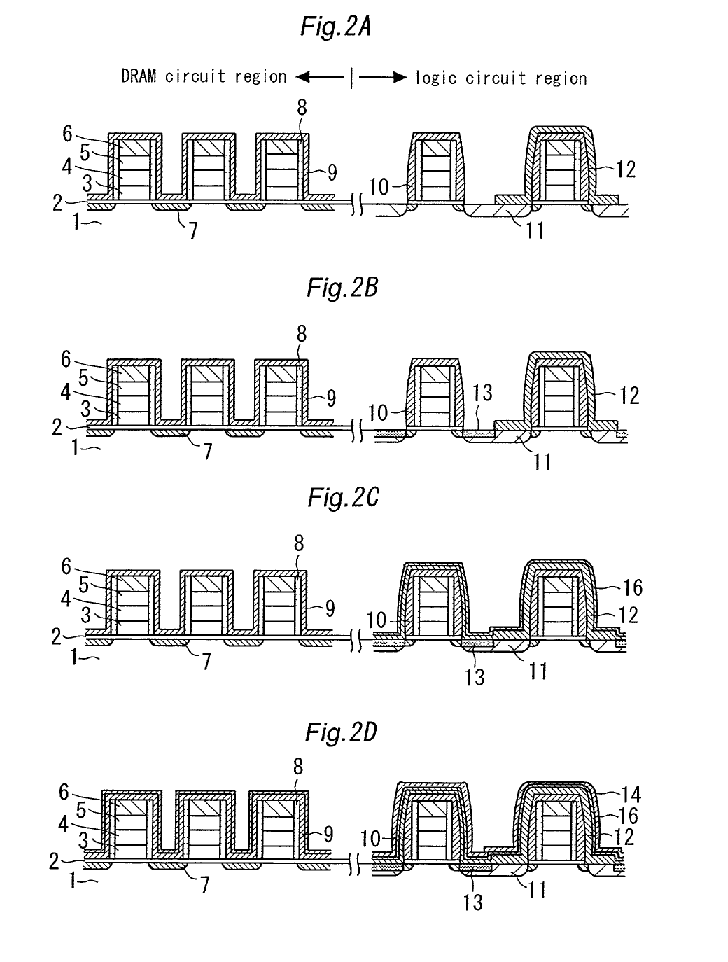

The silicide protection film formed in the DRAM circuit region and the silicide protection film formed in the predetermined region of the logic circuit region are removed by means of etching. As shown in FIG. 2A, a silicide protection film 12 remains in only the logic circuit region exclusive of a predetermined region of the diffused layer formed around predetermined gate electrodes.

Even when the silicide protection film 12 is removed from the DRAM circuit region, the first insulating film 9 formed in the preceding step acts as a silicide protection film. Hence, no silicide layer is formed in the DRAM circuit region on the semiconductor substrate 1.

As shown in FIG. 2B, a silicide layer 13 is formed from, e.g., CoSi₂, in a predetermined region on the diffused layer in the logic circuit region by means of a conventional technique; i.e., a salicide method. In the manner as mentioned above, the silicide layer 13 is formed on the diffused layer of the logic circuit.

By means of the LPCVD method, a buffer film 16 is formed from, e.g., a TEOS film, on the entire surface of the semiconductor substrate 1. At this time, there is used an LPCVD system having a load lock mechanism for preventing oxidation of the silicide layer, or the internal temperature of a CVD reactor to which the semiconductor substrate 1 is to be introduced is set to 400° C. or less. Alternatively, the buffer film 16 may be formed under conditions such that the silicide layer is not subjected to oxidizing reaction.

A resist pattern is formed on the buffer film 16, and the buffer film 16 is subjected to wet etching while the resist pattern is used as a mask. By means of etching, the buffer film 16 is removed from the DRAM circuit region. As shown in FIG. 2C, the buffer film 16 remains on only the semiconductor substrate or on the silicide layer in the logic circuit region.

As shown in FIG. 2D, the second insulating film 14 is formed from, e.g., a nitride film, on the entire surface of the semiconductor substrate 1 by means of the LPCVD method.

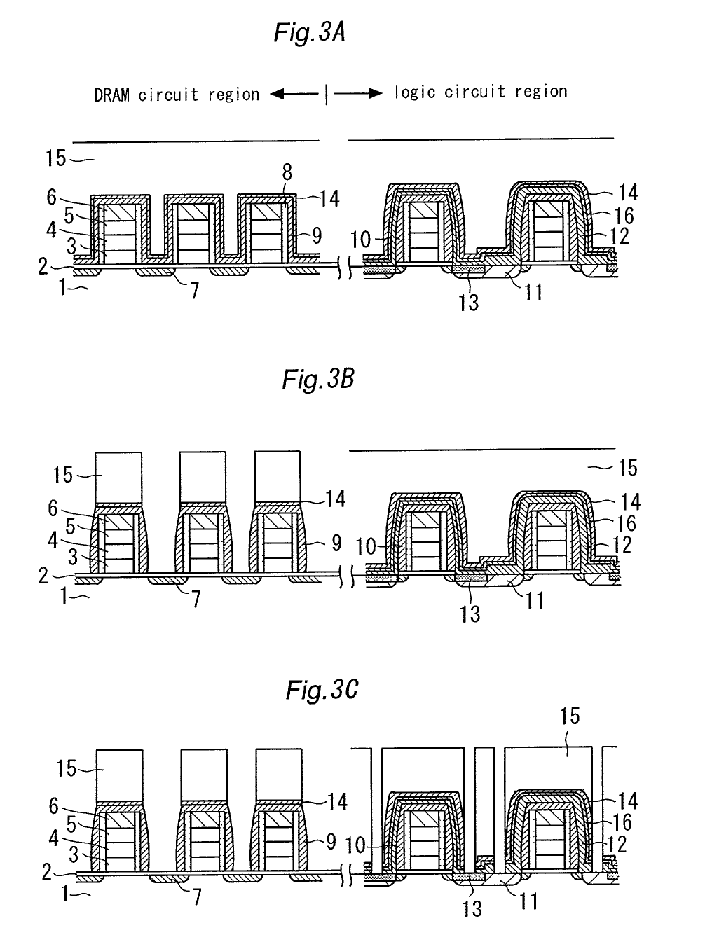

As shown in FIG. 3A, an interlayer insulating film 15 is formed from a BPSG film by means of the APCVD method. The semiconductor substrate 1 is subjected to high-temperature treatment in a steam (wet) atmosphere composed of, for example, hydrogen and oxygen in the proportions of 1.8:1. By means of the heat treatment, the interlayer insulating film 15 becomes fluidized (reflowed). As a result, the smoothness of the interlayer insulating film 15 in the logic circuit region is improved. Further, the space between the gate electrodes located in the DRAM circuit region is embedded with the interlayer insulating film 15.

Even when the semiconductor substrate 1 is subjected to high-temperature treatment in the steam (wet) atmosphere, the second insulating film 14 still remains on the semiconductor substrate 1 or the silicide layer 13 in the logic circuit region. Hence, the semiconductor substrate 1 or the silicide layer 13 located in the logic circuit region is protected from oxidation.

Next, a resist pattern is formed on the interlayer insulating film 15 formed in the DRAM region. As shown in FIG. 3B, the interlayer insulating film 15 is subjected to dry etching while the resist pattern is used as a mask. Subsequently, the first insulating film 9 and the second insulating film 14 are subjected to dry etching while the interlayer insulating film 15 is used as a mask.

As a result of dry etching, contact holes are formed in the DRAM circuit region so as to extend from the surface of the interlayer insulating film 15 to the diffused layer 7 by way of contact openings.

A resist pattern is formed on the interlayer insulating film 15 formed in the logic circuit region. As shown in FIG. 3C, the interlayer insulating film 15, the second insulating film 14, the buffer film 16, and the silicide protection film 12 are subjected to dry etching while the resist pattern is used as a mask.

By means of dry etching, there are formed contact holes which extend from the surface of the interlayer insulating film 15 to the diffused layer 11 by way of contact openings, and contact holes which extend from the surface of the interlayer insulating film 15 to the silicide layer 13 by way of contact openings. Simultaneously, there are also formed contact holes, which extend from the surface of the interlayer insulating film 15 to the tungsten silicide film 4 of the gate electrodes by way of contact openings, although not shown.

Subsequently, interconnections and capacitors (not shown) are formed sequentially, whereby there is formed a semiconductor device having the DRAM circuit and the logic circuit mixed thereon.

In the present embodiment, CoSi₂ is used for forming the silicide layer. However, TiSi₂ or MoSi₂ may be used.

In the present embodiment, a TEOS film is used as a buffer film. However, an NSG film may be used as the buffer film.

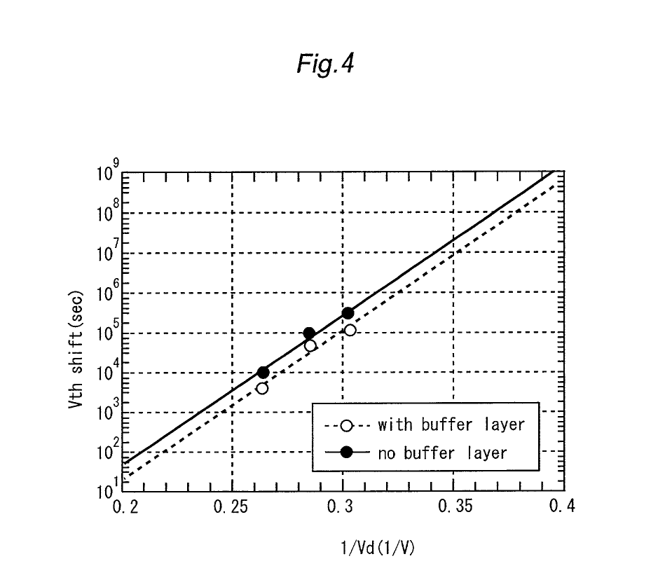

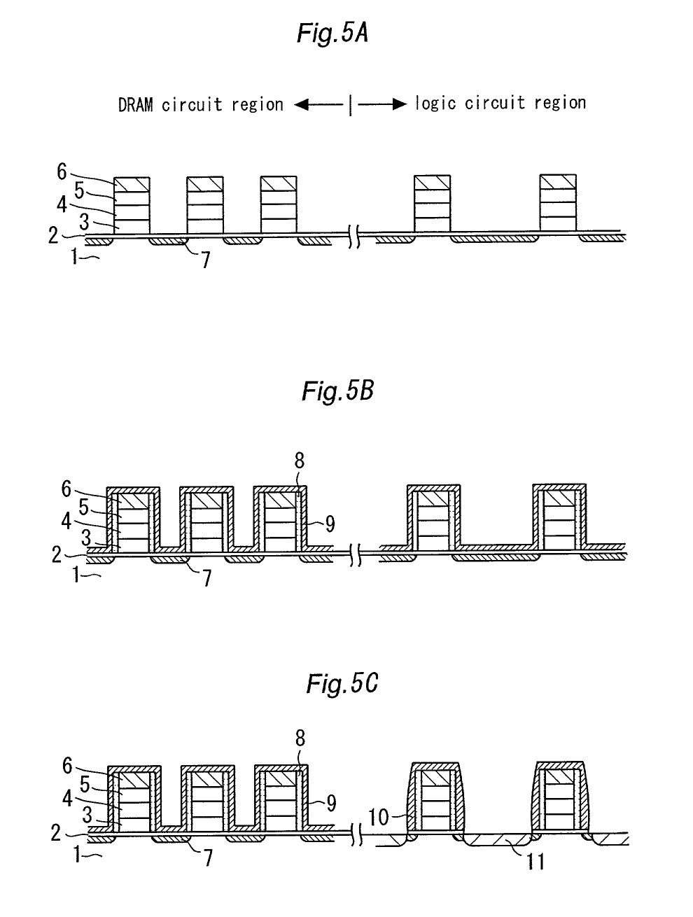

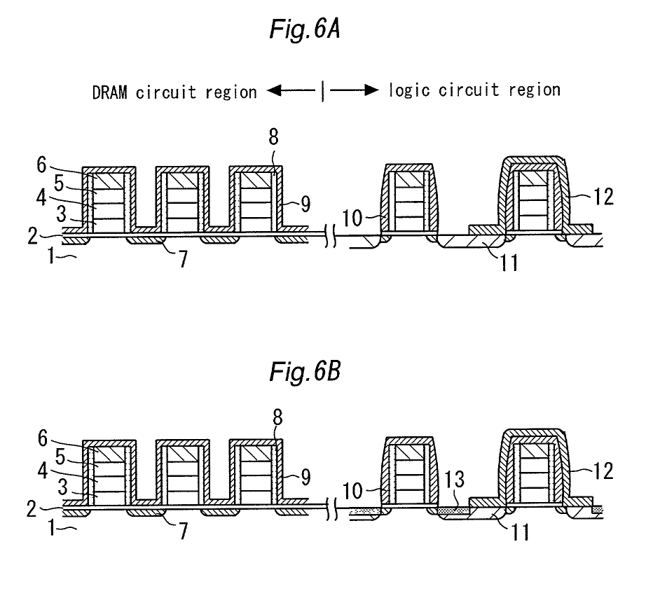

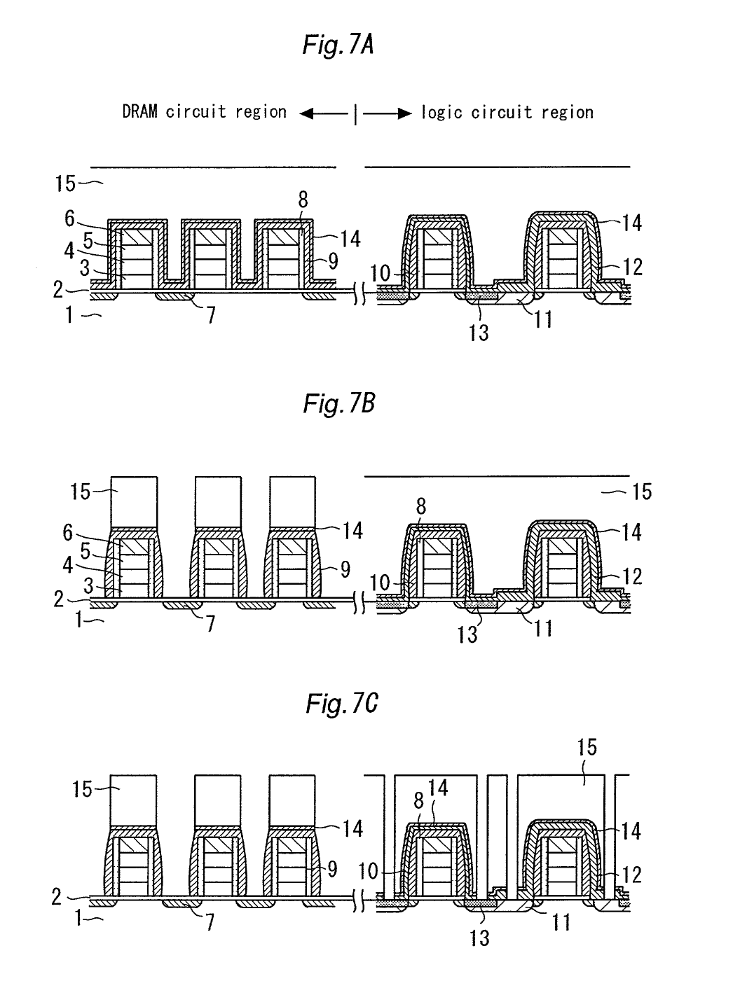

The semiconductor device manufactured according to the above-described method yields the following advantages over that manufactured according to the conventional method. FIG. 4 is a graph showing a hot-carrier characteristic of a transistor, wherein the vertical axis represents a time at which a given amount of change arises in a threshold value and the horizontal axis represents the reciprocal of a drain voltage. Outlined circles and a broken line depict the hot-carrier characteristic of a transistor manufactured according to the conventional method, whereas solid circles and a solid line depict the hot-carrier characteristic of a transistor manufactured by the manufactured method according to the present invention. As shown in the graph, the hot-carrier characteristic of the transistor has been improved by presence of a buffer film.

The present embodiment relates to a method of manufacturing a semiconductor device having a DRAM circuit and a logic circuit formed thereon, that is, so-called eRAM. Needless to say, the manufacturing method according to the present invention can be used as a method of manufacturing a semiconductor device not having a memory region.

The intrinsic feature of the present invention lies in provision of a buffer film between a silicide layer and an insulating film coating the silicide layer. For this reason, the method according to the present invention involves a silicide process and a necessity of coating a silicide layer formed through the silicide process with an insulating film in order to protect the silicide layer treatment to be effected in subsequent processes. Thus, the present invention can be applied to methods of manufacturing all types of semiconductor devices.

The features and advantages of the present invention may be summarized as follows.

According to the present invention, stress imposed on the silicide layer by the insulating film can be alleviated, because a buffer film is formed between a silicide layer formed on a diffused layer (i.e., an impurity region) of a logic circuit, and an insulating film covering the silicide layer when a logic circuit is formed in the semiconductor substrate. As a result, the hot-carrier or p-n junction characteristic of a transistor is improved, and the reliability of a transistor formed in the logic circuit region can be improved.

Further, even when an oxide film is formed as a buffer film, there can be prevented a reduction in the unique effect of the silicide layer; that is, a reduction in the parasitic resistance or parasitic capacitance of the diffused layer, so long as the buffer film is formed under appropriate conditions such that a silicide layer is not oxidized.

Furthermore, in a case where a semiconductor device has both memory and a logic circuit formed thereon, subsequent processes can be facilitated, so long as the buffer film is removed from the DRAM circuit region and is formed only in the logic circuit region.

Obviously many modifications and variations of the present invention are possible in the light of the above teachings. It is therefore to be understood that within the scope of the appended claims the invention may by practiced otherwise than as specifically described.

For example, the present invention includes a method of manufacturing a semiconductor device, which comprises the steps of:

forming a first insulating film so as to cover an upper surface and a side surface of a gate electrode formed on a gate insulating film laid on a semiconductor substrate, and exposing portions of the semiconductor substrate having no gate electrode formed thereon;

forming an impurity region on the surface of the exposed portions of the semiconductor substrate;

forming a silicide layer on the impurity region;

forming a buffer film so as to directly cover the silicide layer; and

forming a second insulating film on the buffer film, wherein the buffer film alleviates stress imposed by the second insulating film on the silicide layer laid on the semiconductor substrate.

The method mentioned above may comprise the steps of:

forming a third insulating film as an interlayer insulating film on the second insulating film; and

forming a contact hole which penetrates through the third insulating film, the second insulating film, and the buffer film and reaches the silicide layer.

Wherein the semiconductor substrate is a silicon substrate; a silicon nitride film can be used as the first and second insulating films; and a silicon oxide film can be used as the buffer film.

The present invention also includes a method of manufacturing a semiconductor device including a memory region and a logic circuit region on a semiconductor substrate, the method comprises the steps of:

forming a first insulating film so as to cover an upper surface and a side surface of a gate electrode formed on a gate insulating film within the logic circuit region, and exposing portions of the semiconductor substrate, which are located in the logic circuit region, and have no gate electrode formed therein;

forming an impurity region on the surface of the semiconductor substrate;

forming a silicide layer on the surface of the impurity region;

forming a buffer film, which directly covers the silicide layer, in the memory region and in the logic circuit region having the silicide layer formed thereon;

forming a resist pattern on top of at least the silicide layer within the logic circuit region, and removing the buffer film from the memory region by means of etching while the resist pattern is used as a mask; and

forming a second insulating film in the logic circuit region and the memory region from which the buffer film has been removed,

wherein the buffer film alleviates stress imposed by the second insulating film on the silicide layer located within the logic circuit region.

The method mentioned above may further comprise the steps of:

forming a third insulating film as an interlayer insulating film on the second insulating film; and

forming a contact hole which penetrates through the third insulating film, the second insulating film, and the buffer film and reaches the silicide layer.

The present invention also includes a semiconductor device, which comprises

a semiconductor substrate including a memory region and a logic circuit region;

a gate insulating film formed on the semiconductor substrate;

a gate electrode formed on the gate insulating film;

an impurity region formed on the surface of the semiconductor substrate adjacent to the gate electrode;

a silicide layer formed on the surface of the impurity region adjacent to the gate electrode within the logic circuit region; and

a buffer film formed, except for the memory region, to directly cover the silicide layer;

an insulating film formed on the buffer film,

wherein the buffer film alleviates the stress imposed by the insulating film on the silicide layer.

The entire disclosure of a Japanese Patent Application No. 2001-024572, filed on Jan. 31, 2000 including specification, claims, drawings and summary, on which the Convention priority of the present application is based, are incorporated herein by reference in its entirety.

1. A method of manufacturing a semiconductor device, comprising the steps of:
forming a silicide layer on the surface of an impurity region formed on a semiconductor substrate;
forming a buffer film which directly covers the silicide layer; and
forming an insulating film on the buffer film, the buffer film alleviating stress imposed on the silicide layer by the insulating film.

2. The method of manufacturing a semiconductor device according to claim 1, further comprising the steps of:
forming an interlayer insulating film on the insulating film; and
forming a contact hole which penetrates through the interlayer insulating film, the insulating film, and the buffer film and reaches the silicide layer.

3. The method of manufacturing a semiconductor device according to claim 1, wherein an oxide film is formed as the buffer film without oxidizing the silicide layer.

4. The method of manufacturing a semiconductor device according to claim 3, wherein the oxide film is formed through use of a CVD system having a load lock mechanism, without involvement of oxidation of the silicide layer.

5. The method of manufacturing a semiconductor device according to claim 3, wherein the oxide film is formed by setting a temperature, at which the semiconductor substrate is to be introduced into a CVD reactor, at 400° C. or less, without involvement of oxidation of the silicide layer.

6. A method of manufacturing a semiconductor device including a memory region and a logic circuit region on a semiconductor substrate, the method comprising the steps of:
forming a silicide layer on the surface of an impurity region within the logic circuit region;
forming a buffer film, which directly covers the silicide layer, in the logic circuit region having the silicide layer formed thereon and in the memory region;
forming a resist pattern on top of at least the silicide layer within the logic circuit region, and removing the buffer film from the memory region by means of etching with the resist pattern used as a mask; and
forming an insulating film so as to cover the logic circuit region and the memory region, wherein the buffer film alleviates stress imposed by the insulating film on the silicide layer located within the logic circuit region.

7. The method of manufacturing a semiconductor device according to claim 6, further comprising the steps of:
forming an interlayer insulating film on the insulating film; and
forming a contact hole which penetrates through the interlayer insulating film, the insulating film, and the buffer film and reaches the silicide layer.

8. A semiconductor device comprising:
a semiconductor substrate;
a gate insulating film formed on the semiconductor substrate;
a gate electrode formed on the gate insulating film;
an impurity region formed on the surface of the semiconductor substrate adjacent to the gate electrode,
a silicide layer formed on the surface of the impurity regions adjacent to the gate electrode; and
a buffer film formed to directly cover the silicide layer;
an insulating film formed on the buffer film, the buffer film alleviating the stress imposed by the insulating film on the silicide layer.
